(19) United States
(12) Patent Application Publication
(10) Pub. No.: US 2023/0269940 A1
(43) Pub. Date: Aug. 24, 2023

(54) NOR-TYPE MEMORY DEVICE, METHOD OF MANUFACTURING NOR-TYPE MEMORY DEVICE, AND ELECTRONIC APPARATUS INCLUDING MEMORY DEVICE

(71) Applicant: INSTITUTE OF MICROELECTRONICS, CHINESE ACADEMY OF SCIENCES, Beijing (CN)

(72) Inventor: Huilong Zhu, Poughkeepsie, NY (US)

(21) Appl. No.: 18/041,085

(22) PCT Filed: Jul. 5, 2022
(86) PCT No.: PCT/CN2022/103823

§ 371 Date: Feb. 9, 2023

(30) Foreign Application Priority Data
Aug. 2, 2021 (CN) 202110883406.9

(51) Int. Cl. H10B 43/27; H10B 43/10; H01L 23/528; H10B 51/10; H10B 51/20; H01L 29/06; H01L 29/775; H01L 29/66; H01L 29/786; H01L 29/423

(52) U.S. Cl. CPC H10B 43/27; H01L 23/5283; H01L 29/0673; H01L 29/42392; H01L 29/66439; H01L 29/775; H01L 29/78696; H10B 43/10; H10B 51/10; H10B 51/20

(57) ABSTRACT

Disclosed are a NOR-type memory device, a method of manufacturing the NOR-type memory device, and an electronic apparatus including the NOR-type memory device. The NOR-type memory device may include: a first gate stack extending vertically on a substrate, and a gate conductor layer and a memory functional layer; a first semiconductor layer surrounding a periphery of the first gate stack, extending along a sidewall of the first gate stack, and a first source/drain region, a first channel region and a second source/drain region arranged vertically in sequence; a conductive shielding layer surrounding a periphery of the first channel region; and a dielectric layer between the first channel region and the conductive shielding layer. The memory functional layer is located between the first semiconductor layer and the gate conductor layer. A memory cell is defined at an intersection of the first gate stack and the first semiconductor layer.

### CROSS REFERENCE TO RELATED APPLICATION(S)

This application claims priority to Chinese Patent Application No. 202110883406.9, filed on Aug. 2, 2021 and entitled “NOR-type memory device, method of manufacturing NOR-type memory device, and electronic apparatus including memory device”, the entire content of which is incorporated herein in its entirety by reference.

### TECHNICAL FIELD

The present disclosure relates to a field of semiconductors, in particular to a NOR-type memory device, a method of manufacturing the NOR-type memory device, and an electronic apparatus including the memory device.

### BACKGROUND

In a planar device such as a Metal Oxide Semiconductor Field Effect Transistor (MOSFET), a source, a gate and a drain are arranged in a direction substantially parallel to a substrate surface. Due to such an arrangement, the planar device is difficult to be further scaled down. In contrast, in a vertical device, a source, a gate and a drain are arranged in a direction substantially perpendicular to a substrate surface. As a result, the vertical device is easier to be scaled down compared to the planar device.

For the vertical device, an integration density may be increased by being stacked on each other. However, this may lead to poor performance. Because in order to stack a plurality of devices conveniently, polycrystalline silicon is usually used as a channel material, resulting in a greater resistance compared with using monocrystalline silicon as the channel material. In addition, it is also desirable that doping levels in a source/drain region and in a channel may be adjusted separately. Moreover, for memory cells arranged in a three-dimensional (3D) manner, a crosstalk between the memory cells may increase.

### SUMMARY

In view of this, an objective of the present disclosure is at least partially to provide a NOR-type memory device with an improved performance, a method of manufacturing the NOR-type memory device, and an electronic apparatus including the memory device.

According to an aspect of the present disclosure, a NOR-type memory device is provided, including: a first gate stack extending vertically on a substrate, wherein the first gate stack includes a gate conductor layer and a memory functional layer; and a first semiconductor layer surrounding a periphery of the first gate stack and extending along a sidewall of the first gate stack. The memory functional layer is located between the first semiconductor layer and the gate conductor layer. The first semiconductor layer includes a first source/drain region, a first channel region and a second source/drain region arranged in sequence in a vertical direction. A memory cell is defined at an intersection of the first gate stack and the first semiconductor layer. The NOR-type memory device further includes a conductive shielding layer surrounding a periphery of the first channel region of the first semiconductor layer, and a dielectric layer between the first channel region of the first semiconductor layer and the conductive shielding layer.

According to another aspect of the present disclosure, a method of manufacturing a NOR-type memory device is provided, including: providing a plurality of device layers on a substrate, wherein each of the plurality of device layers includes a stack of a first source/drain defining layer, a first channel defining layer and a second source/drain defining layer; forming a processing channel that extends vertically with respect to the substrate to pass through the stack in each device layer; epitaxially growing, through the processing channel, a semiconductor layer on a sidewall of each device layer exposed in the processing channel; forming a gate stack in the processing channel, wherein the gate stack includes a gate conductor layer and a memory functional layer arranged between the gate conductor layer and the semiconductor layer, and a memory cell is defined at an intersection of the gate stack and the semiconductor layer; removing the first channel defining layer in each device layer by a selective etching; and forming a dielectric layer and a conductive shielding layer in sequence in a gap formed by a removal of the first channel defining layer.

According to another aspect of the present disclosure, an electronic apparatus is provided, including the NOR-type memory device described above.

According to the embodiments of the present disclosure, a three-dimensional (3D) NOR-type memory device may be constructed by using a stack of single crystalline material as a constructing block. Therefore, when a plurality of memory cells are stacked, an increase in resistance may be suppressed. In addition, the semiconductor layer may be in a form of a nanosheet, which is particularly beneficial to control a short channel effect of the device, and is also beneficial to reduce a height of the device and increase a number of layers of the device layer to increase an integration density. A conductive shielding layer may be provided between the memory cells to suppress a crosstalk between the memory cells.

### BRIEF DESCRIPTION OF THE DRAWINGS

The above and other objectives, features and advantages of the present disclosure will be more apparent through the following description of the embodiments of the present disclosure with reference to the accompanying drawings, in which:

FIG. 1 to FIG. 20(b) show schematic diagrams of some stages in a process of manufacturing a NOR-type memory device according to the embodiments of the present disclosure; and

FIG. 21 schematically shows an equivalent circuit diagram of a NOR-type memory device according to the embodiments of the present disclosure, where FIGS. 2(a), 12(a), 13(a), 15(a), 19(a) and 20(a) show top views, and FIG. 2(a) shows a position of line AA’ and a position of line BB’,

FIGS. 1, 2(b), 3 to 11, 12(b), 13(b), 14, 15(b), 16(a), 17(a), 18(a), 19(b) and 20(b) show cross-sectional views taken along the line AA’, and

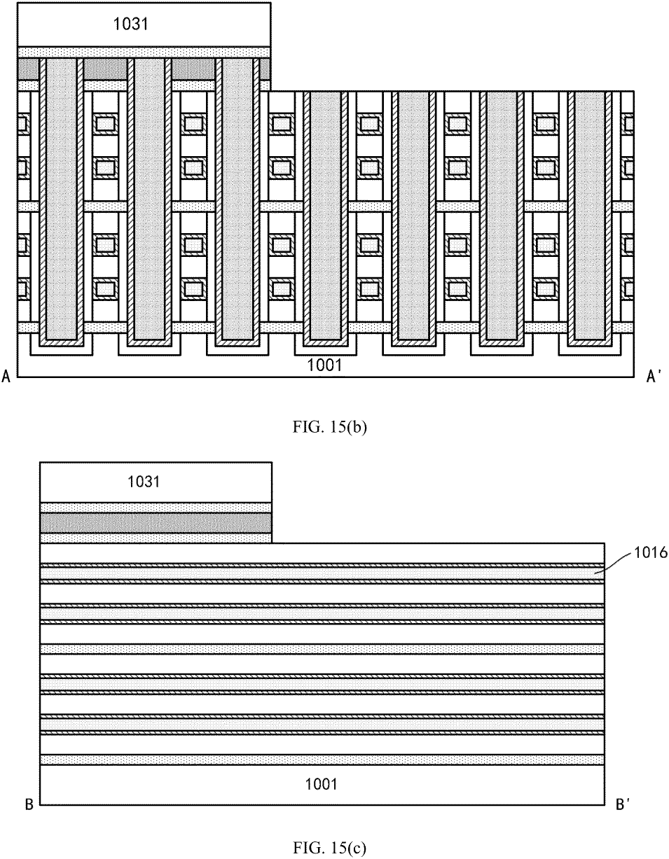

FIGS. 15(c), 16(b), 17(b), 18(b) and 19(c) show cross-sectional views taken along the line BB’.

Throughout the accompanying drawings, the same or similar reference numbers denote the same or similar elements.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In addition, in the following, descriptions of well-known structures and technologies are omitted to avoid unnecessarily obscuring the concepts of the present disclosure.

Various schematic structural diagrams according to the embodiments of the present disclosure are shown in the accompanying drawings. The figures are not drawn to scale. Some details are enlarged and some details may be omitted for clarity of presentation. The shapes of the various regions and layers as well as the relative size and positional relationship thereof shown in the figures are merely exemplary. In practice, there may be deviations due to manufacturing tolerances or technical limitations, and those skilled in the art may additionally design regions/layers with different shapes, sizes and relative positions according to actual needs.

In the context of the present disclosure, when a layer/element is referred to as being located “on” a further layer/element, the layer/element may be located directly on the further layer/element, or there may be an intermediate layer/element between them. In addition, if a layer/element is located “on” a further layer/element in one orientation, the layer/element may be located “under” the further layer/element when the orientation is reversed.

A memory device according to the embodiments of the present disclosure is based on a vertical device. The vertical device may include an active region arranged on a substrate in a vertical direction (a direction substantially perpendicular to a substrate surface), and the active region may include source/drain regions arranged at upper and lower ends of the active region and a channel region located between the source/drain regions. A conductive channel may be formed between the source/drain regions through the channel region. In the active region, the source/drain regions and the channel region may be defined, for example, by doping concentrations.

According to the embodiments of the present disclosure, an active region may be defined by a vertically extending semiconductor layer. Source/drain regions may be formed at opposite ends of the semiconductor layer, respectively, and a channel region may be formed in the middle of the semiconductor layer. A gate stack may extend through the semiconductor layer so that the active region may surround a periphery of the gate stack. Accordingly, the semiconductor layer may be in a form of an annular nanosheet surrounding the gate stack. Here, the gate stack may include a memory functional layer such as at least one of a charge trapping material or a ferroelectric material, so as to achieve a memory function. In this way, the gate stack may cooperate with an opposing active region to define a memory cell. Here, the memory cell may be a flash memory cell.

Due to a characteristic of easy stacking of the vertical device, a plurality of such semiconductor layers may be arranged in the vertical direction. The gate stack may extend vertically to pass through the plurality of semiconductor layers. The plurality of semiconductor layers may be substantially coplanar in the vertical direction, for example, extending along a sidewall of the gate stack. In this way, a single gate stack may intersect with the plurality of semiconductor layers stacked in the vertical direction, so as to define a plurality of memory cells stacked in the vertical direction.

A plurality of such gate stacks may be provided, and each gate stack may similarly pass through a plurality of semiconductor layers, so that a plurality of memory cells are defined at intersections between the plurality of gate stacks and the semiconductor layers. These memory cells may be arranged in a plurality of levels in the vertical direction, and the memory cells in each level may be arranged in an array (for example, generally a two-dimensional array arranged in rows and columns) corresponding to the plurality of gate stacks. Accordingly, a three-dimensional (3D) array of memory cells may be obtained. The memory cells (or semiconductor layers) in each level may be substantially coplanar with each other.

In a NOR-type memory device, each memory cell may be connected to a common source line. In view of this configuration, in order to save wiring, each two memory cells adjacent in the vertical direction may share the same source line connection. For example, the above-mentioned semiconductor layer may have a configuration including a (first) source/drain region, a (first) channel region, a (second) source/drain region, a (second) channel region, and a (third) source/drain region. Then, the first source/drain region, the first channel region and the second source/drain region may cooperate with the gate stack as described above to define a first memory cell, and the second source/drain region, the second channel region and the third source/drain region may cooperate with the gate stack to define a second memory cell. The first memory cell and the second memory cell may be stacked and share the same second source/drain region. The second source/drain region may be electrically connected to the source line.

In order to achieve an electrical connection to the source/drain regions, an interconnection layer in contact with the source/drain regions may be provided. According to the embodiments of the present disclosure, corresponding source/drain regions of memory cells in each level may be electrically connected to bit lines or source lines through the same interconnection layer. Accordingly, the interconnection layer may be formed to surround each source/drain region in the corresponding level, so that the whole of the interconnection layer may have a plate shape, and each semiconductor layer passes through the plate-shaped interconnection layer. The interconnection layer may extend from a device region where the memory cells are located to a contact region that is to be formed, so as to subsequently fabricate a contact portion to the interconnection layer.

The source/drain region may be defined by the corresponding interconnection layer. For example, the source/drain region may be formed by laterally driving a dopant in the interconnection layer into the semiconductor layer. Therefore, the interconnection layer may be substantially coplanar with the corresponding source/drain region in a lateral direction.

A conductive shielding layer may extend between adjacent interconnection layers to surround peripheries of the semiconductor layers in the respective levels. A dielectric layer may be located between the conductive shielding layer and the semiconductor layer and between the conductive shielding layer and the interconnection layer. The conductive shielding layer may suppress a crosstalk between memory cells.

Such a vertical memory device may be manufactured, for example, as follows. Specifically, a plurality of device layers may be provided on a substrate, and each device layer may include a stack of a first source/drain defining layer, a first channel defining layer, and a second source/drain defining layer (and optionally a second channel defining layer and a third source/drain defining layer). For example, these layers may be provided by an epitaxial growth, and may be of a single crystalline semiconductor material. During the epitaxial growth, a thickness of each grown layer, especially a thickness of the channel defining layer, may be controlled. In addition, during the epitaxial growth, an in-situ doping may be performed on each layer in the stack, especially the source/drain defining layer, so as to achieve a desired doping polarity and a desired doping concentration. In this case, the channel defining layer may have etching selectivity with respect to the source/drain defining layer.

A sacrificial layer may be formed between at least some of or even all of adjacent device layers. Such a sacrificial layer may be then replaced by an isolation layer to electrically isolate adjacent bit lines. The sacrificial layer may have an etching selectivity with respect to the device layers.

A processing channel extending vertically with respect to the substrate may be formed to pass through the stack in each device layer. A sidewall of the sacrificial layer may be exposed in the processing channel, so that the sacrificial layer may be replaced by the isolation layer. Through the processing channel, the semiconductor layer may be epitaxially grown on a sidewall of each device layer exposed in the processing channel. Subsequently, the active region of the memory cell, in particular the channel region, may be defined by this semiconductor layer. Therefore, the memory cell may be a nanosheet device, which helps to control a short channel effect. The aforementioned semiconductor layer may be formed by an epitaxial growth, and may be of a single crystal semiconductor material. Compared with a conventional process of forming a plurality of gate stacks stacked on each other and then forming a vertical active region passing through these gate stacks, it is easier to form a single crystalline active region.

A dopant in the source/drain defining layer may be diffused into the semiconductor layer in the lateral direction by an annealing treatment, so as to form the source/drain region in the semiconductor layer. A position of the source/drain region with respect to the substrate may correspond to a position of the corresponding source/drain defining layer with respect to the substrate. In a case that the channel defining layer also contains a dopant, the channel region in the semiconductor layer may also be doped to improve a device performance such as improving the short channel effect, adjusting a threshold voltage, and the like. Through doping properties of the source/drain defining layer and the channel defining layer, it is relatively easier to adjust doping properties of the source/drain region and the channel region, respectively.

Before the growth of the semiconductor layers, the sidewalls of the device layers exposed in the processing channel may be recessed to a certain depth in the lateral direction via the processing channel. The grown semiconductor layers may be located in such recesses and may be substantially coplanar in the vertical direction, so that the gate stack subsequently formed in the processing channel may have a relatively planar surface.

The gate stack may be formed in the processing channel.

In addition, the first channel defining layer (and the second channel defining layer, if any) in each device layer may be removed by selective etching via an additionally formed notch. The dielectric layer and the conductive shielding layer may be sequentially formed in the notch and in a gap formed by the removal of the first channel defining layer (and the second channel defining layer).

The present disclosure may be presented in various forms, some examples of which will be described below. A selection of various materials is involved in the following descriptions. In the selection of materials, in addition to functions of the materials (for example, a semiconductor material may be used to form the active region, a dielectric material may be used to form an electrical isolation, and a conductive material may be used to form an electrode, an interconnection structure, etc.), the etching selectivity is also considered. In the following descriptions, a required etching selectivity may or may not be indicated. It should be clear to those skilled in the art that when etching a material layer is mentioned below, if it is not mentioned or shown that other layers are also etched, then the etching may be selective, and the material layer may have an etching selectivity relative to other layers exposed to a same etching formula.

FIG. 1 to FIG. 20(b) show schematic diagrams of some stages in a process of manufacturing a NOR-type memory device according to the embodiments of the present disclosure.

As shown in FIG. 1, a substrate 1001 is provided. The substrate 1001 may be in various forms, including but not limited to a bulk semiconductor material substrate such as a bulk Si substrate, a semiconductor-on-insulator (SOI) substrate, a compound semiconductor substrate such as a SiGe substrate, and the like. In the following descriptions, for convenience of explanation, a bulk Si substrate such as a Si wafer is taken as an example for description.

A memory device, such as a NOR-type flash memory, may be formed on the substrate 1001 as follows. A memory cell in the memory device may be an n-type device or a p-type device. Here, an n-type memory cell is taken as an example for description. Accordingly, a p-type well may be formed in the substrate 1001. Thus, the following descriptions, especially the descriptions about a doping type, are directed to a formation of the n-type device. However, the present disclosure is not limited to this.

A sacrificial layer 1003₁ for defining an isolation layer, a first source/drain defining layer 1005₁ for defining a source/drain region, a first channel defining layer 1007₁ for defining a channel region, a second source/drain defining layer 1009₁ for defining a source/drain region, a second channel defining layer 1011₁ for defining a channel region, and a third source/drain defining layer 1013₁ for defining a source/drain region may be formed on the substrate 1001, for example, by an epitaxial growth. The first source/drain defining layer 1005₁, the first channel defining layer 1007₁, the second source/drain defining layer 1009₁, the second channel defining layer 1011₁, and the third source/drain defining layer 1013₁ may then define a position of an active region of the device, and may be referred to as a “device layer”, which is denoted by L1 in figures.

Each layer grown on the substrate 1001 may be a single crystalline semiconductor layer. Because the layers are grown or doped separately, a crystal interface or a doping concentration interface may exist between these layers.

The sacrificial layer 1003₁ may be subsequently replaced by an isolation layer for isolating the device from the substrate, and a thickness of the sacrificial layer may correspond to a desired thickness of the isolation layer, for example, in a range of about 10 nm to 50 nm. According to a circuit design, the sacrificial layer 1003₁ may not be provided. The first source/drain defining layer 1005₁, the second source/drain defining layer 1009₁ and the third source/drain defining layer 1013₁ may be doped (for example, doped in situ while being grown) to define a source/drain region with a thickness, for example, in a range of about 20 nm to 50 nm. The first channel defining layer 1007₁ and the second channel defining layer 1011₁ may define a gate length, and may have a thickness corresponding to a desired gate length, for example, in a range of about 15 nm to 100 nm.

These semiconductor layers may contain various suitable semiconductor materials, for example, an elemental semiconductor material such as Si or Ge, a compound semiconductor material such as SiGe, and the like. Considering the following processes, adjacent semiconductor layers in these semiconductor layers may have an etching selectivity between each other. For example, the sacrificial layer 1003₁, the first channel defining layer 1007₁ and the second channel defining layer 1011₁ may contain SiGe (in which an atomic percentage of Ge may be, for example, in a range of about 15% to 30%), while the first source/drain defining layer 1005₁, the second source/drain defining layer 1009₁ and the third source/drain defining layer 1013₁ may contain Si..

The first source/drain defining layer 1005₁, the second source/drain defining layer 1009₁ and the third source/drain defining layer 1013₁ may be doped in situ while being grown, so as to be subsequently used to form the source/drain region. For example, for an n-type device, an n-type doping may be performed, and a doping concentration may be, for example, in a range of about 1E19 cm⁻³ to 1E21 cm⁻³.

In order to increase an integration density, a plurality of device layers may be provided. For example, a device layer L2 may be provided on the device layer L1 by an epitaxial growth, and the device layers may be separated from each other by a sacrificial layer 1003₂ for defining an isolation layer. Only two device layers are shown in FIG. 1, but the present disclosure is not limited thereto. According to a circuit design, the isolation layer may not be provided between some device layers. Similarly, the device layer L2 may include a first source/drain defining layer 1005₂, a first channel defining layer 1007₂, a second source/drain defining layer 1009₂, a second channel defining layer 1011₂, and a third source/drain defining layer 1013₂. Corresponding layers in respective device layers may have the same or similar thickness and/or material, or may have different thicknesses and/or materials. Here, for ease of description only, it is assumed that the device layers L1 and L2 have the same configuration.

For convenience of patterning, a hard mask layer 1015 may be provided on the layers formed on the substrate 1001. For example, the hard mask layer 1015 may contain a nitride (e.g., silicon nitride) and have a thickness in a range of about 50 nm to 200 nm.

A sacrificial layer 1003₃ for defining an isolation layer may be arranged between the hard mask layer 1015 and the device layer L2. As for the sacrificial layers 1003₂ and 1003₃, reference may be made to the above descriptions of the sacrificial layer 1003₁. Moreover, considering the following processes, the thicknesses of the sacrificial layers 1003₁, 1003₂ and 1003₃ may be different from, for example, less than the thicknesses of the channel defining layers 1007₁, 1011₁, 1007₂ and 1011₂.

In the following, on one hand, a processing channel that may reach the sacrificial layer is required, so that the sacrificial layer may be replaced by an isolation layer; and on the other hand, it is required to define a region for forming a gate. According to the embodiments of the present disclosure, the two may be performed in combination. Specifically, a gate region may be defined by using the processing channel.

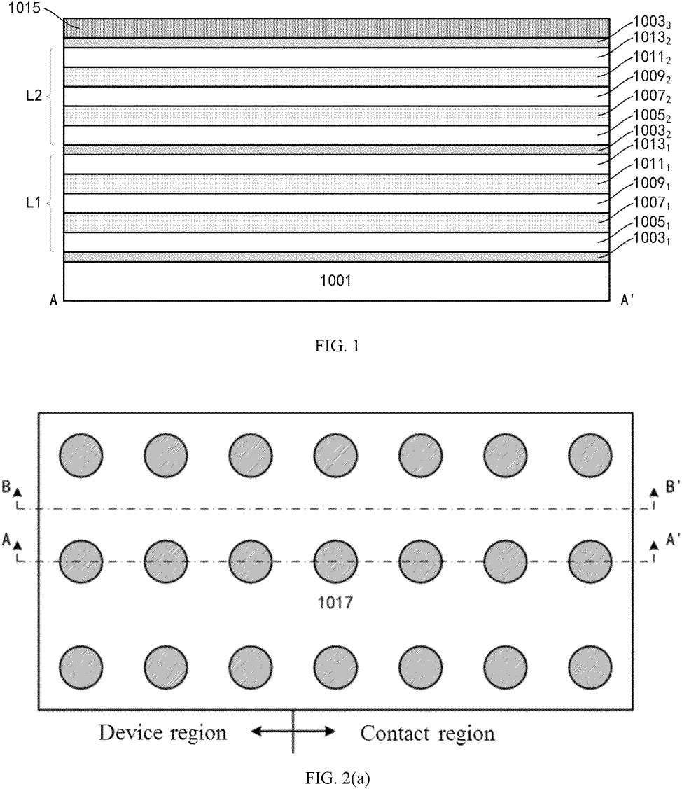

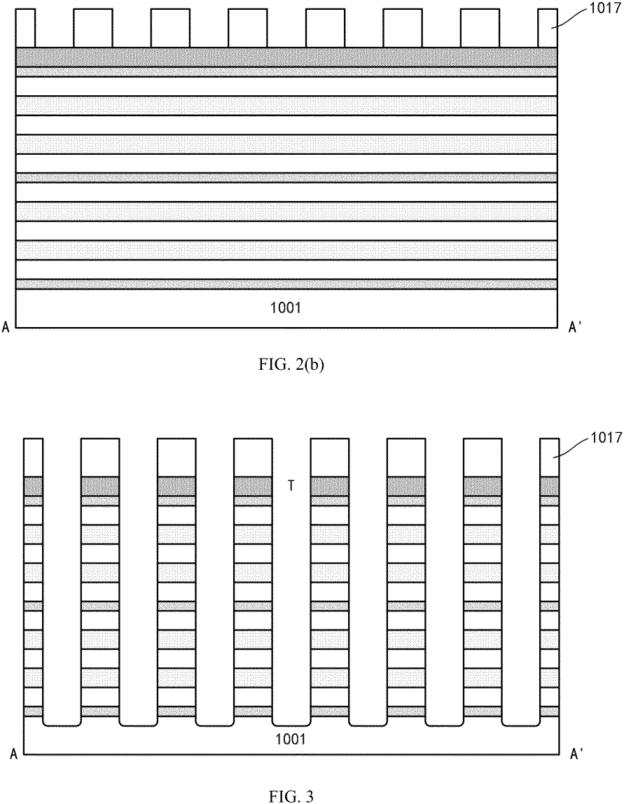

For example, as shown in FIG. 2(a) and FIG. 2(b), a photoresist 1017 may be formed on the hard mask layer 1015 and may be patterned by photolithography to have a series of openings that may define a position of the processing channel. The openings may be of various suitable shapes, such as circle, rectangle, square, polygon, etc., and may have suitable sizes, such as a diameter or a side length in a range of about 20 nm to 500 nm. Considering the following processes, the sizes of the openings may be greater than the thicknesses of the sacrificial layers 1003₁, 1003₂ and 1003₃ and the thicknesses of the channel defining layers 1007₁, 1011₁, 1007₂ and 1011₂. Here, these openings may be arranged in a form of an array (especially in the device region), for example, a two-dimensional array in a horizontal direction and a vertical direction on a paper plane in FIG. 2(a). The array may then define an array of memory cells. FIG. 2(a) shows openings formed on the substrate (which includes a device region for subsequently fabricating memory cells and a contact region for subsequently fabricating contact portions) with a substantially uniform size and a substantially uniform density, but the present disclosure is not limited thereto. The size and/or density of the openings may be changed. For example, a density of openings in the contact region may be less than a density of openings in the device region, so as to reduce a resistance in the contact region.

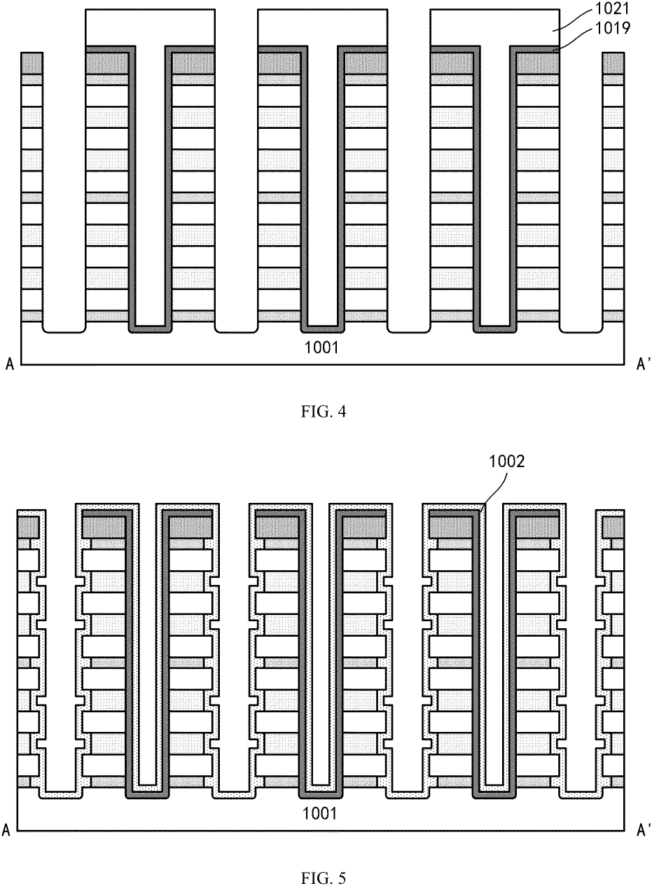

As shown in FIG. 3, the layers on the substrate 1001 may be etched, using the photoresist 1017 patterned in such manner as an etching mask, by an anisotropic etching such as Reactive Ion Etching (RIE), so as to form a processing channel T. The RIE may be performed in a substantially vertical direction (e.g., a direction perpendicular to the substrate surface) and may be performed into the substrate 1001. Accordingly, a series of vertical processing channels T may be formed on the substrate 1001. The processing channels T in the device region may further define a gate region. After that, the photoresist 1017 may be removed.

Then, the sidewall of the sacrificial layer is exposed in the processing channel T. The sacrificial layer may be then replaced by an isolation layer via the exposed sidewall. Considering a support function for the device layers L1 and L2 during replacement, a support layer may be formed.

For example, as shown in FIG. 4, a support material layer may be formed on the substrate 1001, for example, by a deposition such as Chemical Vapor Deposition (CVD). The support material layer may be formed in a substantially conformal manner. Considering the etching selectivity, especially the etching selectivity with respect to the hard mask layer 1015 (a nitride in this example) and the subsequently formed isolation layer (an oxide in this example), the support material layer may contain, for example, SiC. For example, by forming a photoresist 1021 and performing a selective etching such as RIE in cooperation with the photoresist 1021, the support material layer in some processing channels T may be removed and the support material layer in the other processing channels T may be left. The left support material layer may form a support layer 1019. In this way, on one hand, the sacrificial layer may be replaced through the processing channels in which the support layer 1019 is not formed, and on the other hand, the device layers L1 and L2 may be supported by the support layer 1019 in the other processing channels. After that, the photoresist 1021 may be removed.

An arrangement of the processing channels in which the support layer 1019 is formed and the processing channels in which the support layer 1019 is not formed may be achieved by the patterning of the photoresist 1021, and the processing channels may be distributed substantially uniformly for process consistency and uniformity. As shown in FIG. 4, the processing channels in which the support layer 1019 is formed and the processing channels in which the support layer 1019 is not formed may be arranged alternately.

Accordingly, the sacrificial layer may be replaced via the process channels while the device layer is supported by the support layer 1019. However, in this example, both the sacrificial layer and the channel defining layer contain SiGe. In this case, an operation of replacing with the isolation layer may affect the channel defining layer. A protective plug self-aligned to the channel defining layer may be formed to prevent the channel defining layer from being affected by the operation of replacing with the isolation layer. It should be noted that the operation of forming the protective plug may be omitted in a case that the sacrificial layer and the channel defining layer have etching selectivity with respect to each other.

For example, as shown in FIG. 5, the channel defining layers 1007₁, 1011₁, 1007₂ and 1011₂ may be recessed relatively (with respect to the upper and lower source/drain defining layers) in the lateral direction by a selective etching. Atomic Layer Etching (ALE) may be used to control an etching depth well. Accordingly, a protective gap self-aligned to the channel defining layer may be formed. After that, a protective plug may be formed in the protective gap. Here, the sacrificial layers 1003₁ to 1003₃ may be also relatively recessed, so that an isolation gap is formed.

In order to prevent the protective plug from being formed in the isolation gap and thereby hindering the replacement of the sacrificial layer, a position holding plug may be formed in the isolation gap. For example, a position holding material layer 1002 may be formed by a deposition. A deposition thickness of the position holding material layer 1002 may be greater than half of a thickness of the isolation gap (i.e., the thickness of the sacrificial layer), and less than half of a thickness of the protective gap (i.e., the channel defining layer). In addition, since the size of the processing channel is relatively large, the processing channel may not be fully filled with the position holding material layer 1002. Atomic Layer Deposition (ALD) may be used to control the deposition thickness well. Considering the etching selectivity, the position holding material layer 1002 may contain, for example, an oxide.

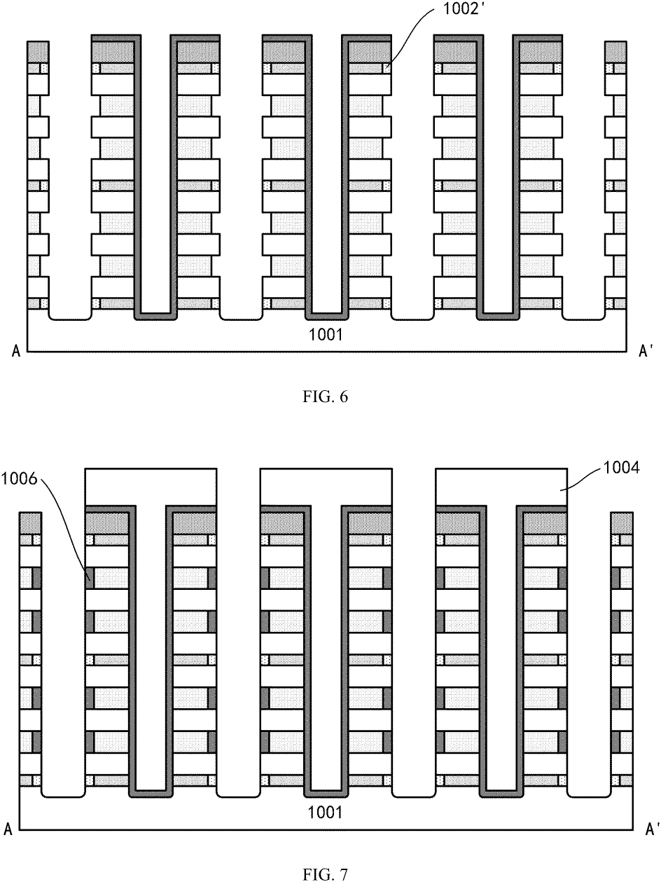

After that, as shown in FIG. 6, a certain thickness of the position holding material layer 1002 may be removed by a selective etching. For example, a removal thickness of the position holding material layer 1002 may be substantially equal to or slightly greater than the deposition thickness of the position holding material layer 1002. Accordingly, the position holding material layer 1002 may be removed from the protective gap and left in the isolation gap, so that a position holding plug 1002′ is formed. ALE may be used to control the removal thickness well.

Next, a protective plug 1006 may be formed in the protective gap, as shown in FIG. 7. For example, the protective plug 1006 may be formed by a deposition followed by RIE in the vertical direction. Considering the etching selectivity (with respect to the position holding plug 1002′ and the hard mask layer 1015), the protective plug 1006 may contain, for example, SiC (which may be removed together with the support layer 1019 which is also SiC in a subsequent process; certainly, the protective plug 1006 may also contain a material different from a material of the support layer 1019, and in this case, the protective plug 1006 may be removed by a separate etching in a subsequent step). During the etching for forming the protective plug 1006, the support layer 1019 may be covered by a photoresist 1004 to prevent the support layer 1019 from being removed. After that, the photoresist 1004 may be removed.

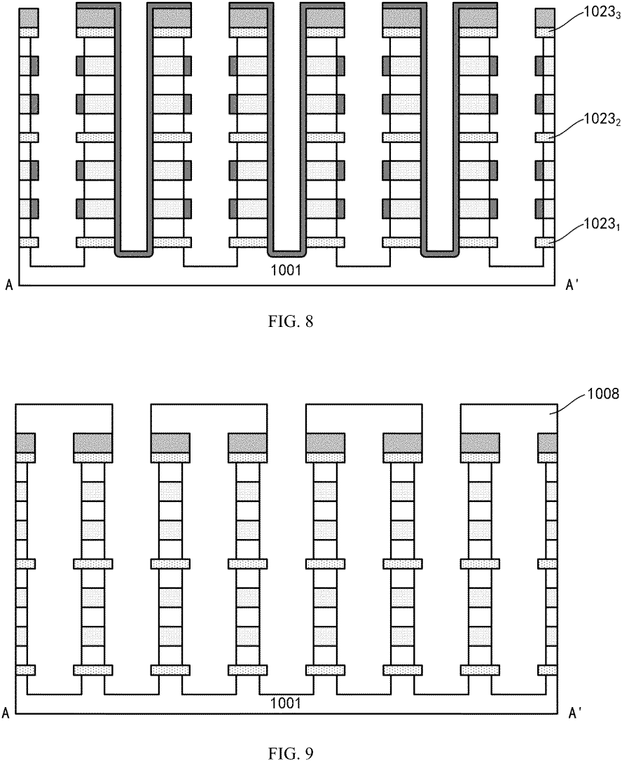

Then, as shown in FIG. 8, the position holding plug 1002′ may be removed by a selective etching via the processing channel T, so as to expose the sacrificial layers 1003₁, 1003₂ and 1003₃, and the exposed sacrificial layers 1003₁, 1003₂ and 1003₃ may be removed by a selective etching. Due to an existence of the support layer 1019, the device layers L1 and L2 may be kept from collapsing. A gap formed by a removal of the sacrificial layers may be filled with a dielectric material by, for example, a process of depositing (preferable ALD to better control a film thickness) and then etching back (e.g., RIE in the vertical direction), so as to form isolation layers 1023₁, 1023₂ and 1023₃. A suitable dielectric material, such as oxide, nitride, SiC or a combination thereof, may be selected for various purposes, such as optimizing isolation reliability, leakage current or capacitance, etc. Considering the etching selectivity, the isolation layers 1023₁, 1023₂ and 1023₃ may contain an oxide (e.g., silicon oxide).

In the above example, in order to form the protective plug 1006, the position holding plug 1002′ is formed firstly. However, the present disclosure is not limited to this. For example, the thickness of the channel defining layer may be less than the thickness of the sacrificial layer. In this case, the protective plug may be formed in the protective gap self-aligned to the channel defining layer according to the method of forming the position holding plug 1002′, so that a space of the isolation gap may be reserved. The sacrificial layer may be exposed by the isolation gap and thus may be replaced.

Since the channel defining layer is relatively recessed previously to form the self-aligned protective plug 1006, considering the subsequent semiconductor layer growth process and the isolation between the grown semiconductor layers, the source/drain defining layer may also be laterally recessed to a certain extent by a selective etching. The source/drain defining layer may be laterally recessed to substantially the same extent as the channel defining layer, so that they may have substantially coplanar sidewalls. Subsequently, the semiconductor layers may be grown on such substantially planar sidewalls.

After that, the support layer 1019 may be removed by a selective etching. The protective plug 1006 may also be removed while the support layer 1019 is removed.

In the processing channels in which the support layer 1019 is not previously formed, a sidewall of a current device layer is laterally recessed to a certain extent with respect to the sidewall of the opening in the hard mask layer 1015 due to the above treatment. In the processing channels in which the support layer 1019 is previously formed, the sidewall of the current device layer is consistent with the sidewall of the opening in the hard mask layer 1015. Considering the isolation between subsequently grown semiconductor layers, the sidewall of the device layer may also be laterally recessed to a certain extent in the processing channels in which the support layer 1019 is previously formed. The sidewall of the device layer in each processing channel may be laterally recessed to substantially the same extent. For example, as shown in FIG. 9, a photoresist 1008 may be formed and may be patterned to cover the processing channels in which the support layer 1019 is not previously formed and to expose the processing channels in which the support layer 1019 is previously formed. Through these exposed processing channels, the device layer may be relatively recessed by a selective etching. The selective etching of the channel defining layer and the selective etching of the source/drain defining layer in the device layer may be performed separately, and the etching depths thereof may be substantially the same. After that, the photoresist 1008 may be removed.

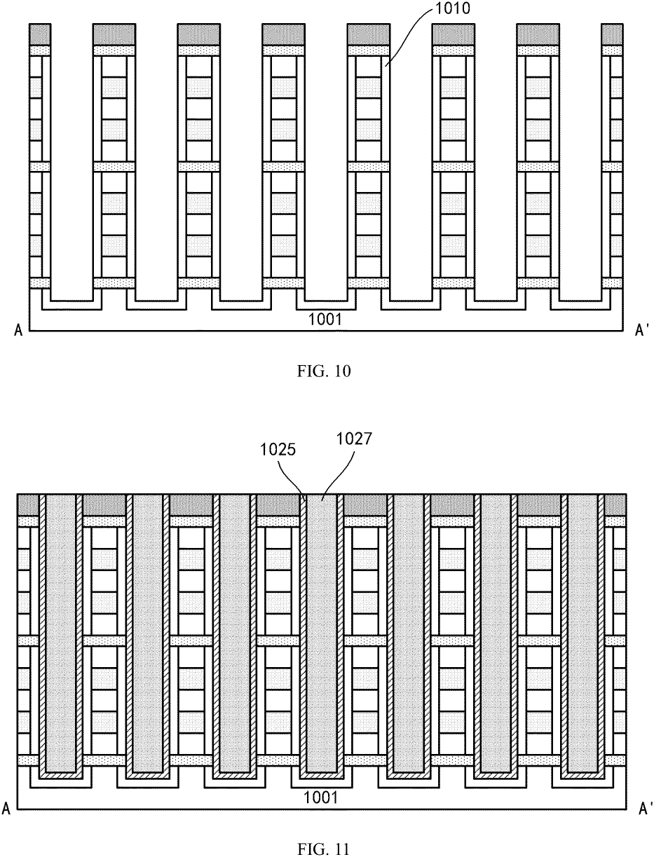

Then, as shown in FIG. 10, a semiconductor layer 1010 may be formed on the sidewall of each of the device layers L1 and L2, for example, by a selective epitaxial growth. The semiconductor layer 1010 may be formed as an annular nanosheet surrounding the processing channel, and may contain various suitable semiconductor materials such as Si. The material and/or thickness of the semiconductor layer 1010 may be selected to improve the device performance. For example, the semiconductor layer 1010 may contain Ge, an IV-IV group compound semiconductor such as SiGe, an III-V group compound semiconductor, etc. to improve a carrier mobility or reduce a leakage current. Semiconductor layers 1010 adjacent in the vertical direction may be isolated from each other by an isolation layer.

An annealing process may be performed to drive the dopant in the source/drain defining layer into the semiconductor layer 1010, so as to form a source/drain region in a portion of the semiconductor layer 1010 corresponding in height to the source/drain defining layer. Since the semiconductor layer 1010 is relatively thin, a process parameter such as an annealing time may be controlled so that a doping distribution in the semiconductor layer 1010 may be mainly affected by the lateral diffusion from the device layer but is substantially not affected or is slightly affected by a diffusion in the vertical direction. The channel defining layer may also be doped in-situ while being grown, so that a certain doping distribution may be formed in a portion of the semiconductor layer 1010 corresponding in height to the channel defining layer during the annealing process, so as to define the doping property of the channel region. Alternatively, the semiconductor layer 1010 may be doped in-situ while being grown, so as to define the doping property of the channel region. The doping of the channel region may improve the device performance, such as improving the short channel effect, adjusting the threshold voltage (Vt), etc.

A gate stack may be formed in the processing channel, especially in the processing channel in the device region. In order to form a memory device, a memory function may be achieved by the gate stack. For example, the gate stack may include a memory structure, such as a charge trapping material or a ferroelectric material.

As shown in FIG. 11, a memory functional layer 1025 and a gate conductor layer 1027 may be formed sequentially, for example, by a deposition. The memory functional layer 1025 may be formed in a substantially conformal manner, and the gate conductor layer 1027 may fill a gap left in the processing channel T after the memory functional layer 1025 is formed. A planarization process such as chemical mechanical polishing (CMP) may be performed on the gate conductor layer 1027 and the memory functional layer 1025 (the CMP may stop at the hard mask layer 1015, for example), so that the gate conductor layer 1027 and the memory functional layer 1025 may be left in the processing channel T to form a gate stack.

The memory functional layer 1025 may be based on a dielectric charge trapping, a ferroelectric material effect, or a band gap engineered charge memory (SONOS), etc. For example, the memory functional layer 1025 may include a dielectric tunneling layer (e.g., an oxide with a thickness in a range of about 1 nm to 5 nm, which may be formed by an oxidation or ALD), a band-offset layer (e.g., a nitride with a thickness in a range of about 2 nm to 10 nm, which may be formed by CVD or ALD), and an isolation layer (e.g., an oxide with a thickness in a range of about 2 nm to 6 nm, which may be formed by an oxidation, CVD or ALD). Such a three-layer structure may result in a band structure that may trap electrons or holes. Alternatively, the memory functional layer 1025 may include a ferroelectric material layer, such as HfZrO₂ with a thickness in a range of about 2 nm to 20 nm.

The gate conductor layer 1027 may contain, for example, a (doped, e.g., p-type doped in a case of an n-type device) polysilicon or a metal gate material.

The channel defining layer may be removed so that the channel region may be completely formed in the semiconductor layer 1010. Then, a nanosheet device may be obtained.

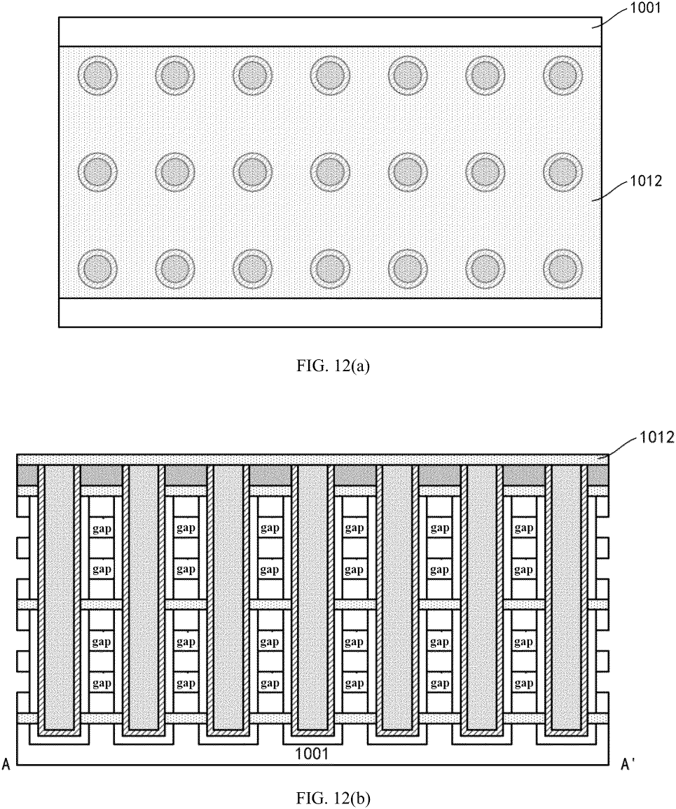

In order to remove the channel defining layer, it is required to form an (additional) processing channel to each channel defining layer (the previously formed processing channels are occupied by the gate stack). For example, as shown in FIG. 12(a) and FIG. 12(b), a mask layer 1012 such as an oxide may be formed on the hard mask layer 1015 and may be patterned to expose a region in which a processing channel needs to be formed. The processing channel may be formed in a place where the gate stack is not arranged. In the examples of FIG. 12(a) and FIG. 12(b), a processing channel extending in a second direction (a horizontal direction on the paper plane of FIG. 12(a)) intersecting with (e.g., perpendicular to) a first direction (a vertical direction on the paper plane of FIG. 12(a)) may be arranged every several memory cells (three memory cells in the example of FIG. 12(a)) in the first direction. Using the mask layer 1012 as an etching mask, each layer under the mask layer 1012 may be etched by an anisotropic etching such as RIE in the vertical direction. The etching may proceed into the substrate 1001 to define the processing channel in which the channel defining layer is exposed. Each channel defining layer may be removed by a selective etching via the processing channel.

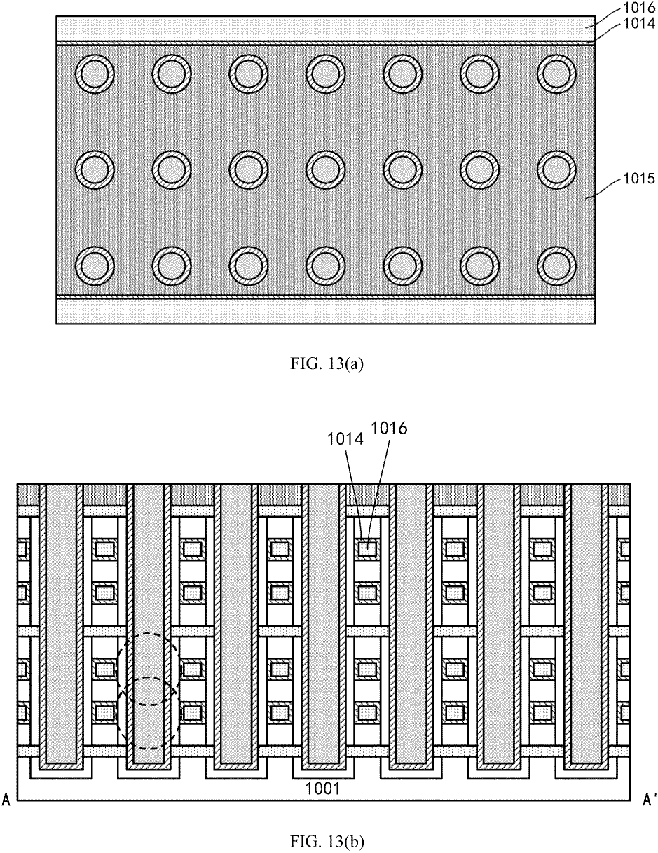

As shown in FIG. 13(a) and FIG. 13(b), a shielding layer 1016 may be formed in a gap (and the processing channel) left by the removal of the channel defining layer. The shielding layer 1016 may contain a conductive material, for example, a metal such as W, a conductive nitride such as TiN, and the like. In addition, a dielectric layer 1014 may be provided between the shielding layer 1016 and the semiconductor layer 1010 and between the shielding layer 1016 and the source/drain defining layer, so as to avoid direct electrical coupling between the shielding layer 1016 and these layers. A combination of the conductive shielding layer 1016 and the dielectric layer 1014 may also serve as a back gate (opposite to the previously formed gate stack across the channel region in the semiconductor layer 1010). The dielectric layer 1014 may contain an oxide or a low-k dielectric such as Al₂O₃ to achieve a good decoupling; or may contain a high-k dielectric such as HfO₂ to achieve a good control of the back gate. The dielectric layer 1014 may be formed in a substantially conformal manner, and the shielding layer 1016 may fill a space remaining after the dielectric layer 1014 is formed in the gap (and the processing channel) left by the removal of the channel defining layer. A planarization process such as CMP may be performed on the shielding layer 1016 and the dielectric layer 1014 (the CMP may stop at the hard mask layer 1015, and the mask layer 1012 may also be removed).

As shown in FIG. 13(b), the gate stack (1025/1027) including the memory functional layer is surrounded by the semiconductor layer 1010. The gate stack may cooperate with the semiconductor layer 1010 to define memory cells, as shown by dashed circles in FIG. 13(b). As described above, the semiconductor layer 1010 may form source/drain regions in portions corresponding to the source/drain defining layers at the upper and lower ends of the semiconductor layer 1010, and form a channel region in a portion corresponding to the channel defining layer in the middle of the semiconductor layer 1010. The channel region may connect the source/drain regions at opposite ends of the semiconductor layer 1010, and the channel region may be controlled by the gate stack.

The gate stack may extend in a pillar shape in the vertical direction and overlap a plurality of semiconductor layers, so as to define a plurality of memory cells stacked in the vertical direction. The memory cells associated with a single gate stack pillar may form a memory cell string. Corresponding to an arrangement of the gate stack pillar (corresponding to the arrangement of the processing channels T described above, e.g., a two-dimensional array), a plurality of such memory cell strings are arranged on the substrate to form a three-dimensional (3D) array of memory cells.

In such embodiments, a single gate stack pillar may define two memory cells in a single device layer, as shown by two dashed circles in the device layer L1 shown in FIG. 13. In the NOR-type memory device, the two memory cells may share the same source/drain region (a portion of the semiconductor layer 1010 corresponding in height to the second source/drain defining layer 1009₁ or 1009₂ in the middle), and may be electrically connected to the source line through the second source/drain defining layer 1009₁ or 1009₂. In addition, the other source/drain regions (portions of the semiconductor layer 1010 corresponding in height to the first source/drain defining layer 1005₁ or 1005₂ and the third source/drain defining layer 1013₁ or 1013₂) of the two memory cells may be electrically connected to different bit lines through the corresponding source/drain defining layers, respectively. That is, the source/drain defining layer may serve as an interconnection structure for electrically connecting the source/drain region of the memory cell to the bit line or the source line. The channel region is formed in the semiconductor layer 1010 in a form of an annular nanosheet, and therefore the device may be a nanosheet or nanowire device, so that the short channel effect may be controlled well and a power consumption may be reduced.

The shielding layer 1016 helps to shield an electric field generated by the memory cells (especially the adjacent ones in the horizontal direction), so as to suppress the crosstalk between the memory cells. In particular, the combination of the shielding layer 1016 and the dielectric layer 1014 (i.e., the “back gate”) may be applied with voltage, for example, through contact portions described below, and thus may be used for at least one selected from shielding the crosstalk between the memory cells, adjusting the threshold voltage of the memory cells, increasing an on-state current, or reducing a leakage current.

In this way, the memory cells (in the device region) may be fabricated. Then, various electrical contact portions may be fabricated (in the contact region) to achieve desired electrical connections.

A stepped structure may be formed in the contact region to achieve electrical connections to respective device layers. A plurality of methods in a related art may be used to form such a stepped structure. According to the embodiments of the present disclosure, the stepped structure may be formed as follows, for example.

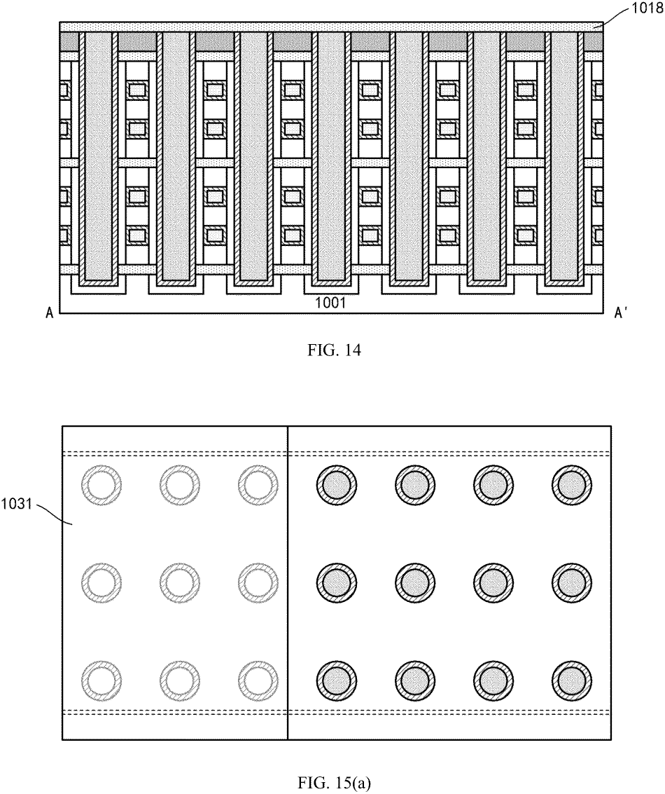

As shown in FIG. 14, a mask layer 1018 may be further formed on the hard mask layer 1015. Considering the etching selectivity, the mask layer 1018 may contain, for example, an oxide.

As shown in FIG. 15(a), FIG. 15(b) and FIG. 15(c), a photoresist 1031 may be formed on the mask layer 1018 and patterned by photolithography to cover the device region and expose the contact region. With the photoresist 1031 as an etching mask, the mask layer 1018, the hard mask layer 1015, the isolation layer 1023₃ and the gate stack may be etched by selective etching such as RIE to expose the device layer. An etching depth may be controlled so that a surface exposed by the photoresist 1031 in the contact region after etching is substantially flat. For example, the mask layer 1018 above the hard mask layer 1015 may be etched firstly to expose the gate stack; then the gate conductor layer 1027 may be etched, and the etching of the gate conductor layer 1027 may stop near a top surface of the device layer L2; and then, the hard mask layer 1015 and the isolation layer 1023₃ may be sequentially etched; after such etching, a top end of the memory functional layer 1025 may protrude above the top surface of the device layer L2 and may be removed by RIE. In this way, a step is formed between the contact region and the device region. After that, the photoresist 1031 may be removed.

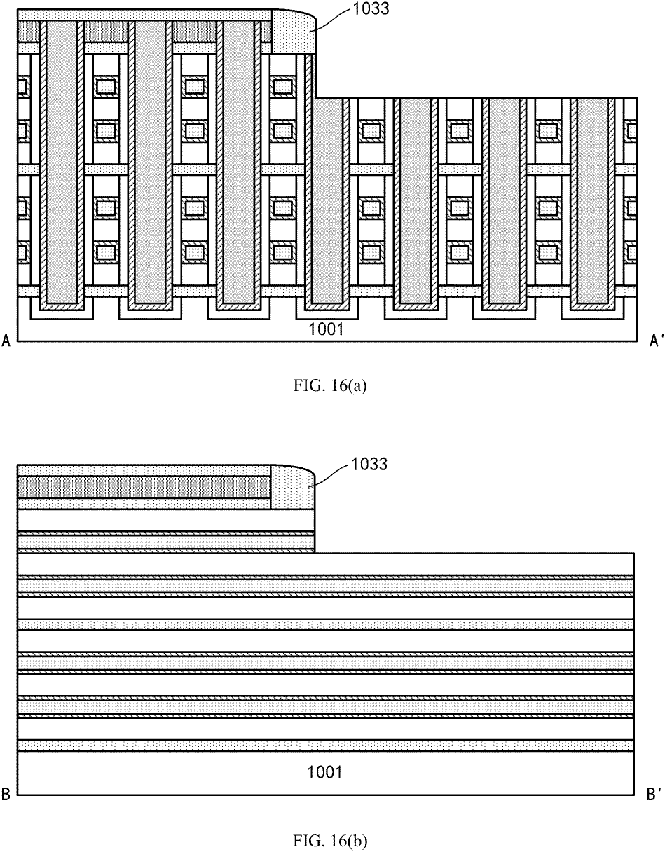

As shown in FIG. 16(a) and FIG. 16(b), a spacer 1033 may be formed at the step between the contact region and the device region through a spacer forming process. For example, a layer of dielectric such as an oxide may be deposited in a substantially conformal manner, then an anisotropic etching such as RIE in the vertical direction may be performed on the deposited dielectric to remove a lateral extension of the deposited dielectric and leave a vertical extension thereof, so as to form the spacer 1033. Here, considering that the mask layer 1018 also contains an oxide, an etching depth of the RIE may be controlled to be substantially equal to or slightly greater than a deposition thickness of the dielectric, so as to avoid completely removing the mask layer 1018 above the hard mask layer 1015. A width of the spacer 1033 (in the horizontal direction in the figures) may be substantially equal to the deposition thickness of the dielectric. The width of the spacer 1033 defines a size of a landing pad for a subsequent contact portion to the third source/drain defining layer 1013₂ in the device layer L2.

With the spacer 1033 thus formed as an etching mask, the third source/drain defining layer 1013₂, the dielectric layer 1014 and the shielding layer 1016 that are exposed and the gate stack may be etched by a selective etching such as RIE to expose the second source/drain defining layer 1009₂ in the device layer L2. An etching depth may be controlled so that a surface exposed by the spacer 1033 in the contact region after etching is substantially flat. For example, the gate conductor layer 1027 may be etched firstly (in a case that the gate conductor layer 1027 contains polysilicon, the third source/drain defining layer 10132 which is Si here may also be at least partially etched), and the etching may stop near a top surface of the second source/drain defining layer 1009₂; then the third source/drain defining layer 1013₂ may be etched (for example, it is not completely etched before; or the gate conductor layer 1027 includes a metal gate, and therefore an etching formula with etching selectivity is used), and the etching may stop at the dielectric layer 1014; then the dielectric layer 1014 and the shielding layer 1016 may be etched, and the etching may stop at the second source/drain defining layer 1009₂; after such etching, the top end of the memory functional layer 1025 may protrude above the top surface of the second source/drain defining layer 1009₂ and may be removed by RIE. In this way, another step is formed between the third source/drain defining layer 1013₂ and the surface exposed by the spacer 1033 in the contact region.

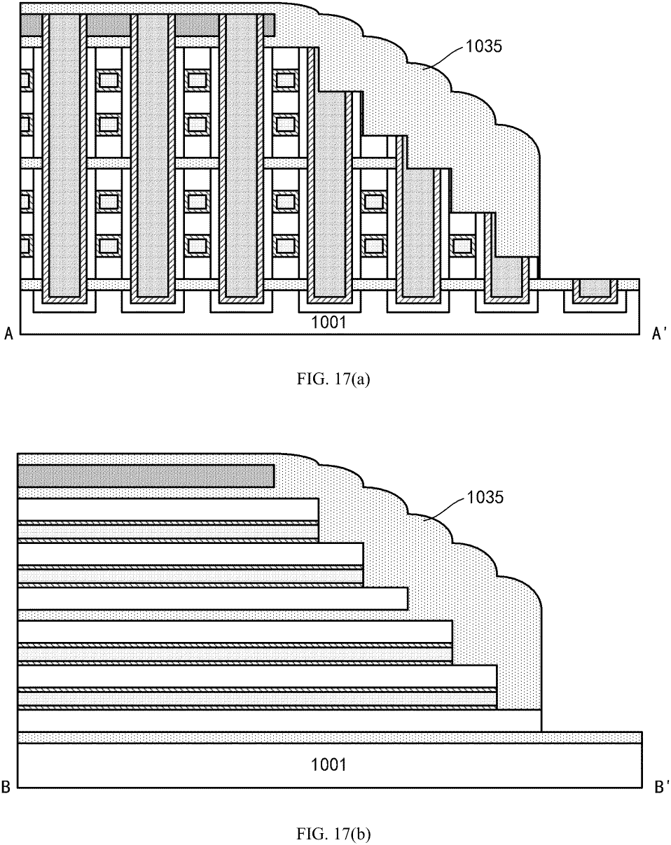

According to the processes described above with reference to FIG. 16(a) and FIG. 16(b), a plurality of steps may be formed in the contact region by forming spacers and etching with the spacers as etching masks, as shown in FIG. 17(a) and FIG. 17(b). These steps form a stepped structure such that an end portion of each layer requiring an electrical connection in each device layer, such as the aforementioned source/drain defining layer, may protrude with respect to an upper layer, so as to define a landing pad of the contact portion to that layer. A portion of each formed spacer left after processing is denoted by 1035 in FIG. 17(a) and FIG. 17(b).

After that, the contact portions may be fabricated.

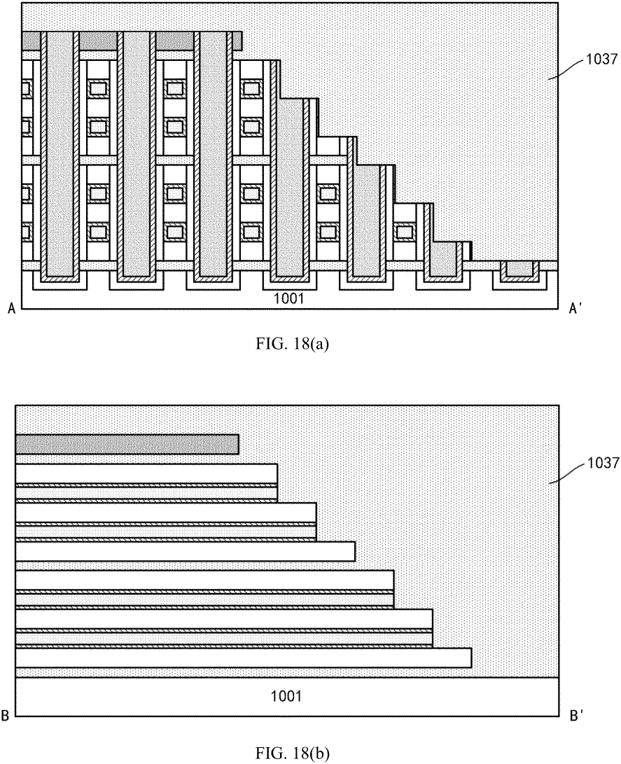

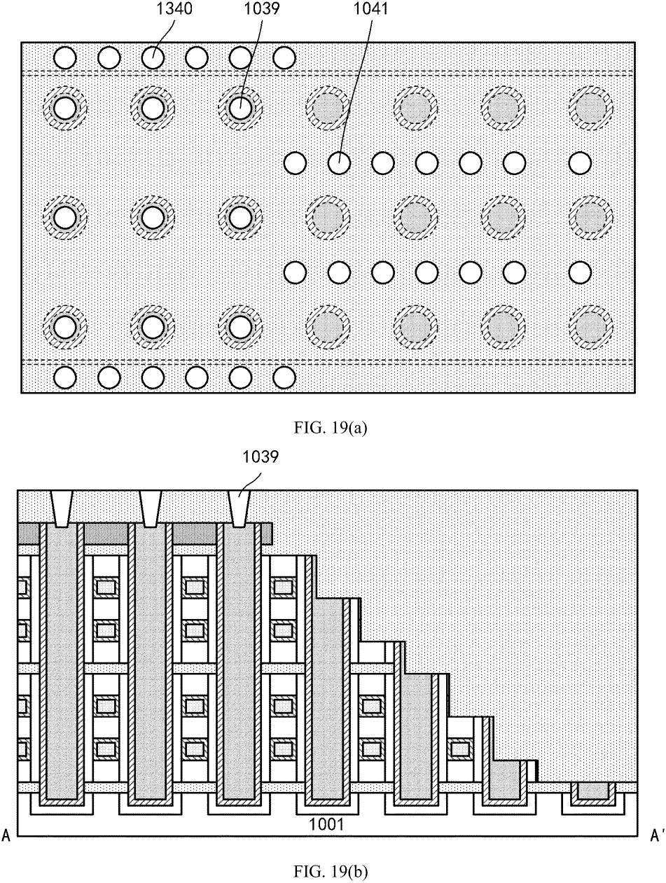

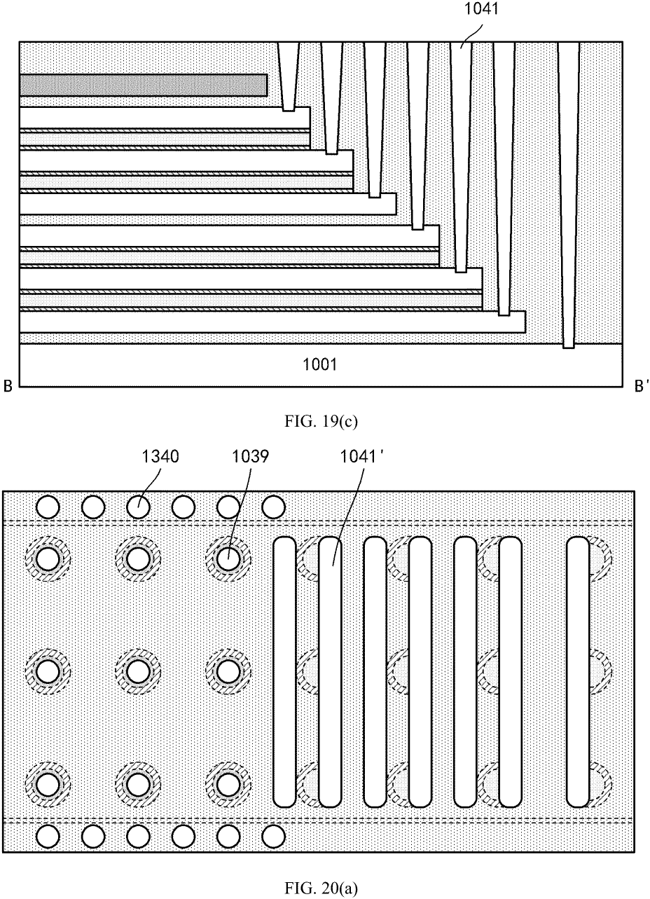

For example, as shown in FIG. 18((a) and FIG. 18(b), an interlayer dielectric layer 1037 may be formed by depositing an oxide and performing a planarization such as CMP. Here, the preceding spacer 1035 and other oxide parts are shown as being integral with the interlayer dielectric layer 1037 as they all contain oxides. Then, as shown in FIG. 19(a), FIG. 19(b) and FIG. 19(c), contact portions 1039, 1040 and 1041 may be formed in the interlayer dielectric layer 1037. Specifically, the contact portion 1039 may be formed in the device region and may be electrically connected to the gate conductor layer 1027 in the gate stack; the contact portion 1040 may be formed in the processing channel as described above with reference to FIG. 12(a) and FIG. 12(b), and may be electrically connected to the shielding layer 1016; and the contact portion 1041 may be formed in the contact region and may be electrically connected to respective source/drain defining layers. The contact portion 1041 in the contact region may avoid remaining gate stacks in the contact region. These contact portions may be formed by etching holes in the interlayer dielectric layer 1037 and filling the holes with a conductive material such as a metal.

Here, the contact portion 1039 may be electrically connected to a word line. Through the word line, a gate control signal may be applied to the gate conductor layer 1027 via the contact portion 1039. For two memory cells stacked in a device layer, the source/drain defining layer in the middle, i.e., the second source/drain defining layer 1009₁ or 1009₂ may be shared by the two memory cells and may be electrically connected to the source line via the contact portion 1041; and the source/drain defining layers located at the upper and lower ends, i.e., the first source/drain defining layers 1005₁ or 1005₂ and the third source/drain defining layers 1013₁ or 1013₂, may be electrically connected to different bit lines via the contact portion 1041. In this way, a NOR-type configuration may be obtained.

Here, forming two memory cells in one device layer may reduce the number of wires. However, the present disclosure is not limited to this. For example, it is possible to form a single memory cell in one device layer. In this case, only the first source/drain defining layer, the first channel defining layer and the second source/drain defining layer may be provided in the device layer, and the second channel defining layer and the third source/drain defining layer are not required.

In the above-described embodiments, the contact portion 1041 in the contact region needs to avoid the remaining gate stacks in the contact region. According to other embodiments of the present disclosure, an isolation such as a dielectric material may be formed on top ends of the remaining gate stacks in the contact region, so that it is not required to intentionally avoid these remaining gate stacks.

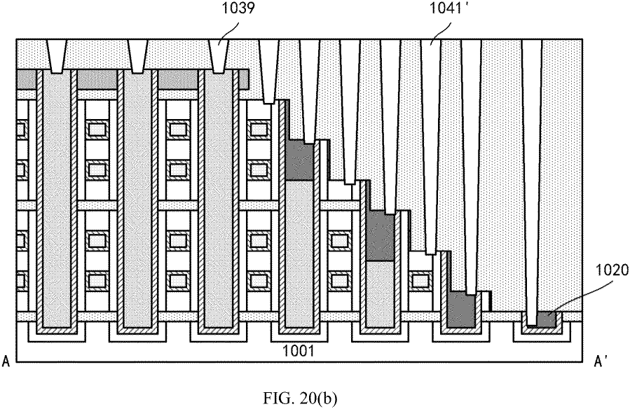

For example, as shown in FIG. 20(a) and FIG. 20(b), after the stepped structure is formed in the contact region as described above with reference to FIG. 15(a) to FIG. 17(b), the spacers 1035 may be removed by a selective etching such as RIE, so as to expose the top ends of the gate stacks (in the device region and the contact region). The gate stacks in the device region may be covered by a shielding layer such as a photoresist, while the gate stacks in the contact region may be exposed. For the gate stack exposed in the contact region, the gate conductor layer may be recessed, for example, by about 50 nm to 150 nm, by a selective etching such as RIE. After that, the shielding layer may be removed. A gap formed by the recess of the gate conductor layer in the contact region may be filled with a dielectric material such as SiC, for example, by deposition and then etching back, so as to form an isolation plug 1020.

Then, an interlayer dielectric layer may be formed and contact portions 1039, 1040 and 1041′ may be formed therein according to the above-described embodiments. In this example, the contact portion 1041′ in the contact region may extend into the isolation plug 1016. Therefore, the contact portion 1041′ may not be limited to the above-mentioned plug form, but may be formed in a bar shape to reduce contact resistance. The bar-shaped contact portion 1041′ may extend along the landing pads (i.e., steps in the stepped structure) of the corresponding layer.

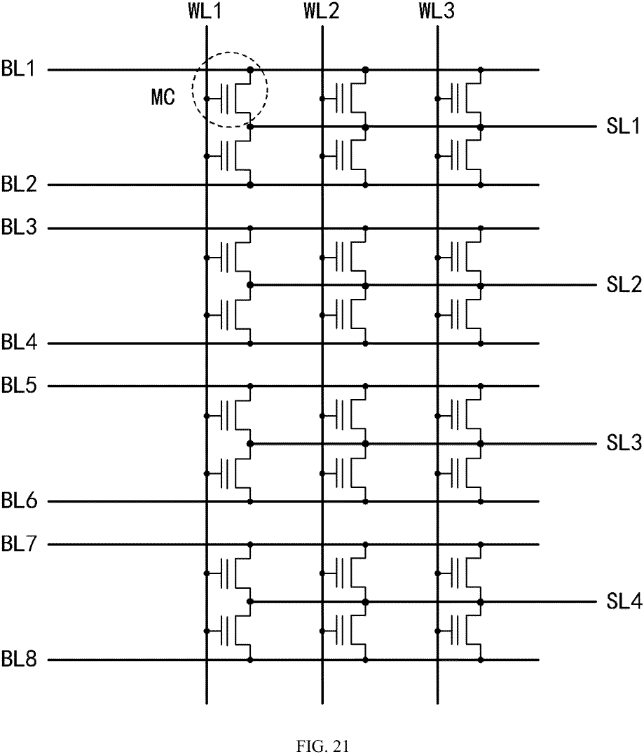

FIG. 21 schematically shows an equivalent circuit diagram of a NOR-type memory device according to the embodiments of the present disclosure.

In the example of FIG. 21, three word lines WL1, WL2 and WL3 and eight bit lines BL1, BL2, BL3, BL4, BL5, BL6, BL7 and BL8 are schematically shown. However, the specific numbers of the bit lines and the word lines are not limited to this. A memory cell MC is provided at an intersection of the bit line and the word line. FIG. 21 further shows four source lines SL1, SL2, SL3 and SL4. As described above, memory cells in two adjacent layers in the vertical direction may share the same source line connection. Moreover, the source lines may be connected to each other, so that the memory cells MC may be connected to a common source line.

Here, a two-dimensional array of the memory cells MC is shown for convenience of illustration only. A plurality of such two-dimensional arrays may be arranged in a direction intersecting with this two-dimensional array (for example, a direction perpendicular to the paper surface of the figures), so as to obtain a three-dimensional array.

In FIG. 21, an extending direction of the word lines WL1 to WL3 may correspond to an extending direction of the gate stack, which is the vertical direction with respect to the substrate in the above-described embodiments. In this direction, adjacent bit lines are isolated from each other. This is also a reason for providing the isolation layer between adjacent device layers in the vertical direction in the above-described embodiments.

The memory device according to the embodiments of the present disclosure may be applied to various electronic apparatuses. For example, the memory device may store various programs, applications and data required for operations of the electronic apparatus. The electronic apparatus may further include a processor in cooperation with the memory device. For example, the processor may operate the electronic apparatus by executing a program stored in the memory device. The electronic apparatus may include, for example, a smart phone, a personal computer (PC), a tablet computer, an artificial intelligence device, a wearable device, a mobile power supply, or the like.

In the above descriptions, the technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

The embodiments of the present disclosure have been described above. However, these embodiments are for illustrative purposes only, and are not intended to limit the scope of the present disclosure. The scope of the present disclosure is defined by the appended claims and their equivalents. Those skilled in the art may make various substitutions and modifications without departing from the scope of the present disclosure, and these substitutions and modifications should all fall within the scope of the present disclosure.

What is claimed is:

1. A NOR-type memory device, comprising:
a first gate stack extending vertically on a substrate, wherein the first gate stack comprises a gate conductor layer and a memory functional layer; and
a first semiconductor layer surrounding a periphery of the first gate stack and extending along a sidewall of the first gate stack,
wherein the memory functional layer is located between the first semiconductor layer and the gate conductor layer,
wherein the first semiconductor layer comprises a first source/drain region, a first channel region and a second source/drain region arranged in sequence in a vertical direction, and
wherein a memory cell is defined at an intersection of the first gate stack and the first semiconductor layer,
the NOR-type memory device further comprises a conductive shielding layer surrounding a periphery of the first channel region of the first semiconductor layer, and a dielectric layer between the first channel region of the first semiconductor layer and the conductive shielding layer.

2. The NOR-type memory device according to claim 1, further comprising:
a first interconnection layer extending laterally to surround a periphery of the first source/drain region of the first semiconductor layer; and
a second interconnection layer extending laterally to surround a periphery of the second source/drain region of the first semiconductor layer,
wherein the dielectric layer is further located between the conductive shielding layer and the first interconnection layer and between the conductive shielding layer and the second interconnection layer.

3. The NOR-type memory device according to claim 2, further comprising:
a plurality of first gate stacks, wherein each of the plurality of first gate stacks extends vertically through the first interconnection layer and the second interconnection layer;
a plurality of first semiconductor layers extending along sidewalls of corresponding first gate stacks to surround the periphery of each first gate stack respectively, wherein each of the plurality of first semiconductor layers is located at substantially a same height with respect to the substrate and extends vertically through the first interconnection layer and the second interconnection layer,
wherein the conductive shielding layer extends laterally between the first interconnection layer and the second interconnection layer to surround a periphery of each first semiconductor layer, and the dielectric layer extends to be located between the conductive shielding layer and the first semiconductor layer, between the conductive shielding layer and the first interconnection layer, and between the conductive shielding layer and the second interconnection layer.

4. The NOR-type memory device according to claim 3,
wherein each first semiconductor layer further comprises a second channel region and a third source/drain region arranged in sequence in the vertical direction, and the second channel region is located between the second source/drain region and the third source/drain region in the vertical direction, so that two memory cells stacked with each other are defined at the intersection of the first gate stack and each first semiconductor layer,
the NOR-type memory device further comprises:
a third interconnection layer extending laterally to surround a periphery of the third source/drain region of each first semiconductor layer;
a further conductive shielding layer extending laterally between the second interconnection layer and the third interconnection layer to surround the periphery of each first semiconductor layer; and
a further dielectric layer located between the further conductive shielding layer and the first semiconductor layer, between the further conductive shielding layer and the second interconnection layer, and between the further conductive shielding layer and the third interconnection layer,
wherein the first interconnection layer, the second interconnection layer and the third interconnection layer comprise a notch extending in the vertical direction, the conductive shielding layer and the further conductive shielding layer extend integrally in the notch, and the dielectric layer and the further dielectric layer extend integrally in the notch.

5. The NOR-type memory device according to claim 4, wherein the substrate comprises a device region and a contact region adjacent to the device region, and the memory cell is formed on the device region,
wherein the first interconnection layer, the second interconnection layer and the third interconnection layer respectively extend from the device region to the contact region in a first direction, and
wherein the notch extends in the first direction.

6. The NOR-type memory device according to claim 5, further comprising:
a first bit line and a second bit line different from the first bit line; and
a source line,
wherein the first interconnection layer and the third interconnection layer are electrically connected to the first bit line and the second bit line respectively, and the second interconnection layer is electrically connected to the source line.

7. The NOR-type memory device according to claim 4, wherein the first interconnection layer, the second interconnection layer and the third interconnection layer contain a doped single crystalline semiconductor material.

8. The NOR-type memory device according to claim 3, further comprising:
a plurality of second semiconductor layers extending along sidewalls of corresponding first gate stacks to surround the periphery of each first gate stack respectively, wherein each second semiconductor layer is located at substantially a same height with respect to the substrate but different from the height of the first semiconductor layer, and comprises a first source/drain region, a first channel region and a second source/drain region arranged in sequence in the vertical direction;
a third interconnection layer extending laterally to surround a periphery of the first source/drain region of each second semiconductor layer;
a fourth interconnection layer extending laterally to surround a periphery of the second source/drain region of each second semiconductor layer;
a further conductive shielding layer extending laterally between the third interconnection layer and the fourth interconnection layer to surround a periphery of each second semiconductor layer; and
a further dielectric layer located between the further conductive shielding layer and the second semiconductor layer, between the further conductive shielding layer and the third interconnection layer, and between the further conductive shielding layer and the fourth interconnection layer,
wherein the first interconnection layer, the second interconnection layer, the third interconnection layer and the fourth interconnection layer comprise a notch extending in the vertical direction, the conductive shielding layer and the further conductive shielding layer extend integrally in the notch, and the dielectric layer and the further dielectric layer extend integrally in the notch.

9. The NOR-type memory device according to claim 4, further comprising:
a contact portion to the conductive shielding layer on the notch.

10. The NOR-type memory device according to claim 1, wherein the memory functional layer contains at least one of a charge trapping material or a ferroelectric material.

11. The NOR-type memory device according to claim 1, wherein the semiconductor layer contains a single crystalline semiconductor material.

12. The NOR-type memory device according to claim 8, wherein the first semiconductor layer and the second semiconductor layer extending around a same first gate stack are substantially coplanar in the vertical direction.

13. The NOR-type memory device according to claim 8, wherein an isolation layer is provided between the first semiconductor layer and the second semiconductor layer.

14. The NOR-type memory device according to claim 8, wherein the first semiconductor layer is a vertically extending nanosheet with an annular cross-section, and the second semiconductor layer is a vertically extending nanosheet with an annular cross-section.

15. The NOR-type memory device according to claim 1, wherein the conductive shielding layer and the dielectric layer form a second gate stack.

16. The NOR-type memory device according to claim 15, wherein the second gate stack is configured for at least one selected from: shielding a crosstalk between memory cells, adjusting a threshold voltage of the memory cell, increasing an on-state current, or reducing a leakage current.

17. A method of manufacturing a NOR-type memory device, comprising:
providing a plurality of device layers on a substrate, wherein each of the plurality of device layers comprises a stack of a first source/drain defining layer, a first channel defining layer and a second source/drain defining layer;
forming a processing channel that extends vertically with respect to the substrate to pass through the stack in each device layer;
epitaxially growing, through the processing channel, a semiconductor layer on a sidewall of each device layer exposed in the processing channel;
forming a gate stack in the processing channel, wherein the gate stack comprises a gate conductor layer and a memory functional layer arranged between the gate conductor layer and the semiconductor layer, and a memory cell is defined at an intersection of the gate stack and the semiconductor layer;
removing the first channel defining layer in each device layer by a selective etching; and
forming a dielectric layer and a conductive shielding layer in sequence in a gap formed by a removal of the first channel defining layer.

18. The method according to claim 17, wherein the stack of at least one of the plurality of device layers further comprises a second channel defining layer and a third source/drain defining layer,
the method further comprises:
removing the second channel defining layer in each device layer by a selective etching,
wherein the dielectric layer and the conductive shielding layer are further formed in a gap formed by a removal of the second channel defining layer.

19. The method according to claim 17, wherein the stack is formed by an epitaxial growth.

20. The method according to claim 19, wherein at least each source/drain defining layer in the stack is doped in-situ when being grown epitaxially.

21. The method according to claim 20, further comprising:
performing an annealing process so that a dopant in the stack diffuses laterally into the semiconductor layer.

22. The method according to claim 17, further comprising:
etching via the processing channel so that the sidewall of the device layer exposed in the processing channel is recessed laterally by a depth.

23. The method according to claim 17, further comprising:
forming a sacrificial layer between at least one pair of adjacent device layers,
wherein the method further comprises replacing the sacrificial layer by an isolation layer after providing the plurality of device layers.

24. The method according to claim 17, wherein,
the removing the first channel defining layer comprises:
forming a notch in the stack; and
removing the first channel defining layer via the notch,
the forming a dielectric layer and a conductive shielding layer comprises:
forming the dielectric layer in a substantially conformal manner in the
notch and in a gap formed by a removal of the first channel defining layer; and
forming the conductive shielding layer on the dielectric layer.

25. The method according to claim 24, further comprising:
forming, on the notch, a contact portion to the conductive shielding layer.

26. An electronic apparatus, comprising the NOR-type memory device according to claim 1.

27. The electronic apparatus according to claim 26, wherein the electronic apparatus comprises a smart phone, a personal computer, a tablet computer, an artificial intelligence device, a wearable device, or a mobile power supply.
